(19) United States
(12) Patent Application Publication
(10) Pub. No.: US 2026/0173587 A1
(43) Pub. Date: Jun. 18, 2026

(54) LIGHT-EMITTING DIODE AND DISPLAY DEVICE

(71) Applicant: QUANZHOU SANAN SEMICONDUCTOR TECHNOLOGY CO., LTD., Quanzhou (CN)

(72) Inventors: Jing WANG, Quanzhou (CN); Yang YANG, Quanzhou (CN); Huanshao KUO, Quanzhou (CN); Yuren PENG, Quanzhou (CN)

(21) Appl. No.: 19/414,361

(22) Filed: Dec. 10, 2025

(30) Foreign Application Priority Data
Dec. 12, 2024 (CN) 202411829696.9

(51) Int. Cl. H10H 20/815; H10H 20/824; H10H 20/831

(52) U.S. Cl. CPC H10H 20/815; H10H 20/831; H10H 20/824

(57) ABSTRACT

A light-emitting diode and a display device are provided. The light-emitting diode includes a semiconductor stack and an electrode structure. The semiconductor stack includes a first semiconductor layer, an active layer, and a second semiconductor layer sequentially stacked from top to bottom. The electrode structure includes a first electrode electrically connected to the first semiconductor layer and a second electrode electrically connected to the second semiconductor layer. A semiconductor contact layer is formed between the first semiconductor layer and the first electrode. The first electrode includes a metal contact layer and a metal electrode layer sequentially stacked above the semiconductor contact layer. The metal contact layer contains Ni, and the metal electrode layer is a multilayer structure or an alloy structure including at least Au. Based on the described structure, the metal contact layer and the semiconductor contact layer can be uniformly diffused to form good ohmic contact.

### CROSS-REFERENCE TO RELATED APPLICATION

This application claims priority to Chinese patent application No. CN202411829696.9, filed to China National Intellectual Property Administration (CNIPA) on Dec. 12, 2024, which is herein incorporated by reference in its entirety.

### TECHNICAL FIELD

The disclosure relates to the field of semiconductor devices, and more particularly to a light-emitting diode and a display device.

### BACKGROUND

Light-emitting diodes (LEDs) are widely used in various fields, such as display devices, vehicle lamps, and general lighting lamps, due to their high reliability, long lifespan, and low power consumption.

With the gradual expansion of the augmented reality/virtual reality (AR/VR) market, the application demand of micro-LEDs in AR/VR is also growing. In the process of pursuing more compact and lightweight applications, the size requirements for micro-LEDs are gradually decreasing, with chip sizes needing to be reduced to 5 micrometers (μm), 2 μm, or even less than 2 μm. In AR applications, micro-LED products often have chip sizes less than 5 μm, and significant brightness loss occurs due to the shielding of axial electrodes. When the chip size is less than 5 μm, a light-emitting surface is almost entirely blocked by electrodes.

Micro-LED products in the related art usually have a trapezoidal structure, with a reflective system below and a light emitting surface above. However, since the chip size is reduced to 5 μm or less, the size of the electrodes on the light-emitting surface is limited to be smaller. Currently, the N-side electrode uses a metal-semiconductor contact approach, where interdiffusion between the metal and semiconductor forms an ohmic contact. In traditional metal-semiconductor contact structures, metal diffusion points are relatively large in particle size and sparsely distributed. When applied to ultra-small micro-LED products, this leads to inconsistent ohmic contact characteristics and resistances from chip to chip, resulting in non-uniform brightness and abnormal flickering when a screen is illuminated.

### SUMMARY

In view of defects and shortcomings of micro-LEDs in the related art, an objective of the disclosure is to provide a light-emitting diode and a display device.

To achieve the above objective and other related objectives, in a first aspect, the disclosure provides a light-emitting diode, including: a semiconductor stack and an electrode structure.

The semiconductor stack includes a first semiconductor layer, an active layer, and a second semiconductor layer sequentially stacked from top to bottom.

The electrode structure includes a first electrode electrically connected to the first semiconductor layer and a second electrode electrically connected to the second semiconductor layer.

A semiconductor contact layer is formed between the first semiconductor layer and the first electrode. The first electrode includes a metal contact layer and a metal electrode layer sequentially stacked above the semiconductor contact layer, the metal contact layer contains nickel (Ni), and the metal electrode layer is a multilayer structure or an alloy structure including at least gold (Au).

In a second aspect, the disclosure provides a display device, including a substrate and multiple light-emitting units located on the substrate, and the light-emitting units includes the light-emitting diode provided in the disclosure.

As described above, the light-emitting diode and the display device provided by the disclosure offer at least the following beneficial technical effects.

The light-emitting diode of the disclosure at least includes the semiconductor stack and the electrode structure. The semiconductor stack includes the first semiconductor layer, the active layer, and the second semiconductor layer sequentially stacked from top to bottom. The electrode structure includes the first electrode electrically connected to the first semiconductor layer and the second electrode electrically connected to the second semiconductor layer. The semiconductor contact layer is formed between the first semiconductor layer and the first electrode. The first electrode includes the metal contact layer and the metal electrode layer sequentially stacked above the semiconductor contact layer. The metal contact layer contains an Ni layer, and the metal electrode layer is the multilayer structure or the alloy structure including at least Au. As described above, in the disclosure, the metal contact layer, for example containing Ni, is inserted between the semiconductor contact layer and the metal electrode layer. The metal contact layer and the semiconductor contact layer can diffuse uniformly to form an excellent ohmic contact, which facilitates current spreading and ensures uniform light emission from the light-emitting diode. In addition, the aforementioned metal contact layer can effectively prevent the diffusion of Au from the metal electrode layer into the semiconductor contact layer, reducing the self-agglomeration effect of Au. As a result, the diffusion of the metal of the first electrode and the semiconductor contact layer is more uniform, the resistance of the electrodes is more uniform, and the condition of non-uniform brightness is avoided.

### BRIEF DESCRIPTION OF DRAWINGS

FIG. 1 illustrates a schematic structural view of a light-emitting diode according to an embodiment 1 of the disclosure.

FIG. 2 illustrates a schematic partially enlarged structural view of a first electrode in FIG. 1.

FIG. 3 illustrates a scanning electron microscope (SEM) image at a side of the first electrode in FIG. 1.

FIG. 4 illustrates an energy dispersive spectroscopy (EDS) image from respective layers in FIG. 3.

FIG. 5 and FIG. 6 illustrate microscopic magnified images of a contact interface between a first electrode and a semiconductor contact layer in a light-emitting diode in the related art and that in the embodiment 1 of the disclosure, respectively.

FIG. 7 and FIG. 8 illustrate focused ion beam (FIB) test images of longitudinal sections at the side of the first electrode of the light-emitting diode in the related art and that in the embodiment 1 of the disclosure, respectively.

FIG. 9 and FIG. 10 illustrate effect images of a lit display screen formed by the light-emitting diode in the related art and that formed by the light-emitting diode according to embodiment 1 of the disclosure, respectively.

FIG. 11 illustrates a schematic structural view of a light-emitting diode according to an embodiment 2 of the disclosure.

FIG. 12 illustrates a schematic structural view of a display device according to an embodiment 3 of the disclosure.

### DESCRIPTION OF REFERENCE SIGNS

100: substrate; 200: semiconductor stack; 201: first semiconductor layer; 2011: first spacer layer; 2012: first confinement layer (also referred to as first cladding layer); 2013: first window layer; 2014: semiconductor contact layer; 202: active layer; 203: second semiconductor layer; 301: first electrode; 3011: metal contact layer; 3012: metal electrode layer; 302: second electrode; 303: agglomerated particle; 304: diffusion trace; 305: diffusion point; 400: transparent conductive layer; 500: protective insulation layer; and
900: display device; 901: circuit substrate; 902: light-emitting unit; 903: wiring layer; 904: housing.

### DETAILED DESCRIPTION OF EMBODIMENTS

The following describes implementation of the disclosure through specific embodiments. Those skilled in the art can readily understand other advantages and effects of the disclosure from the content disclosed in this specification. The disclosure may also be implemented or applied through other different specific embodiments. Various details in this specification may be modified or changed based on different viewpoints and applications without departing from the spirit of the disclosure.

It should be noted that the drawings provided in the embodiments are intended only to schematically explain the basic concept of the disclosure. The drawings show only components relevant to the disclosure and are not drawn according to the actual number, shape, and dimensions of components during implementation. The actual form, quantity, positional relationship, and proportion of each component during implementation may be arbitrarily changed under the premise of realizing technical solutions of the disclosure, and the layout of the components may also be more complex.

To achieve the objectives of the disclosure and other related objectives, in a first aspect, the disclosure provides a light-emitting diode, including: a semiconductor stack and an electrode structure.

The semiconductor stack includes a first semiconductor layer, an active layer, and a second semiconductor layer sequentially stacked from top to bottom.

The electrode structure includes a first electrode electrically connected to the first semiconductor layer and a second electrode electrically connected to the second semiconductor layer.

A semiconductor contact layer is formed between the first semiconductor layer and the first electrode. The first electrode includes a metal contact layer and a metal electrode layer sequentially stacked above the semiconductor contact layer. The metal contact layer contains Ni, and the metal electrode layer is a multilayer structure or an alloy structure including at least Au.

As described above, in the disclosure, the metal contact layer, for example containing Ni, is inserted between the semiconductor contact layer and the metal electrode layer. The metal contact layer and the semiconductor contact layer can diffuse uniformly to form an excellent ohmic contact, which facilitates current spreading and ensures uniform light emission from the light-emitting diode. In addition, the aforementioned metal contact layer can effectively prevent the diffusion of Au from the metal electrode layer into the semiconductor contact layer, reducing the self-agglomeration effect of Au. As a result, the diffusion of the metal of the first electrode and the semiconductor contact layer is more uniform, the resistance of the electrodes is more uniform, and the condition of non-uniform brightness is avoided.

Diffusion points are formed at an interface between the metal contact layer and the semiconductor contact layer, a size of each diffusion point is less than or equal to 1 μm, and a spacing distance between two adjacent diffusion points is less than or equal to 1 μm.

The aforementioned metal contact layer can effectively prevent the diffusion of Au from the metal electrode layer into the semiconductor contact layer, reducing the self-agglomeration effect of Au. This leads to more uniform diffusion between the metal of the first electrode and the semiconductor contact layer, resulting in a lower surface roughness, i.e., forming a good interface. Consequently, the electrode resistance is more uniform, avoiding non-uniform brightness.

In an embodiment, the metal electrode layer is the alloy structure including the Au, germanium (Ge), Ni.

The material selection for the metal electrode layer described above ensures good conductivity and adhesion of the electrode, improving the stability of the metal electrode layer.

In an embodiment, a content of the Ni in the metal contact layer is greater than a content of the Ni in the metal electrode layer, a content of Au in the metal contact layer is less than a content of the Au in the metal electrode layer, and a content of Ge in the metal contact layer is greater than a content of the Ge in the metal electrode layer.

In an embodiment, the content of Ni in the metal contact layer is greater than or equal to 10 weight percent (wt%).

The distribution of elemental content in the first electrode indicates good diffusivity between the metal contact layer and the metal electrode layer. At the same time, the metal contact layer effectively prevents the self-agglomeration effect during the diffusion of Au from the metal electrode layer into the semiconductor contact layer, improving the uniformity of the electrode structure.

In an embodiment, a thickness of the metal contact layer is in a range of 5 angstroms (Å) to 100 Å.

On one hand, the thickness of the metal contact layer is controlled to ensure that a good ohmic contact layer is formed with the semiconductor contact layer, and on the other hand, the metal contact layer is well fused with each metal layer of the metal electrode layer, so that the stability and the reliability of the electrode structure are ensured, and the obvious light absorption phenomenon cannot be generated.

In an embodiment, a thickness of the metal electrode layer is in a range of 0.02 μm to 1 μm.

The thickness of the metal electrode layer ensures good electrical performance and stability of the electrode structure.

In an embodiment, a material of the semiconductor contact layer is gallium arsenide (GaAs) or aluminum gallium indium phosphide (AlGaInP).

The semiconductor ohmic contact formed by the GaAs or AlGaInP material can form good ohmic contact with the metal contact layer, and the semiconductor ohmic contact and the metal contact layer have good adhesion, so that the stability of the metal electrode is improved.

In an embodiment, the semiconductor stack is an AlGaInP-based semiconductor material layer.

In an embodiment, the first electrode is formed on a side of the first semiconductor layer facing away from the active layer, and the second electrode is formed on a side of the second semiconductor layer facing away from the active layer.

In an embodiment, the first electrode and the second electrode both are formed on a side of the first semiconductor layer facing away from the active layer.

As described above, the light-emitting diode of the disclosure can be a vertical-structure chip or a flip-chip structure. The electrode structure described above has broader application scenarios.

In an embodiment, in a projection onto a plane of the semiconductor stack, a projected area of the first electrode is less than or equal to a projected area of the semiconductor contact layer.

In an embodiment, in a projection onto a plane of the semiconductor stack, a surface area of the first electrode accounts for 50% to 100% of a surface area of the first semiconductor layer.

The surface area setting of the first electrode ensures its good conductivity and stability, avoiding phenomena such as detachment or peeling due to an excessively small area.

In an embodiment, a maximum single-side length of the light-emitting diode is less than or equal to 5 μm.

The first electrode is relatively small, making it more suitable for chips with sizes of 5 μm or less. It can significantly increase the light-emitting area of small-sized chips and improve light extraction efficiency.

In a second aspect, the disclosure provides a display device, including a substrate and multiple light-emitting units located on the substrate. The light-emitting units includes the light-emitting diode provided in the disclosure.

The display device of the disclosure incorporates the aforementioned light-emitting diode, thereby achieving enhanced overall display uniformity and avoiding non-uniform phenomena such as bright spots caused by the self-agglomeration effect of Au in the electrodes.

### Embodiment 1

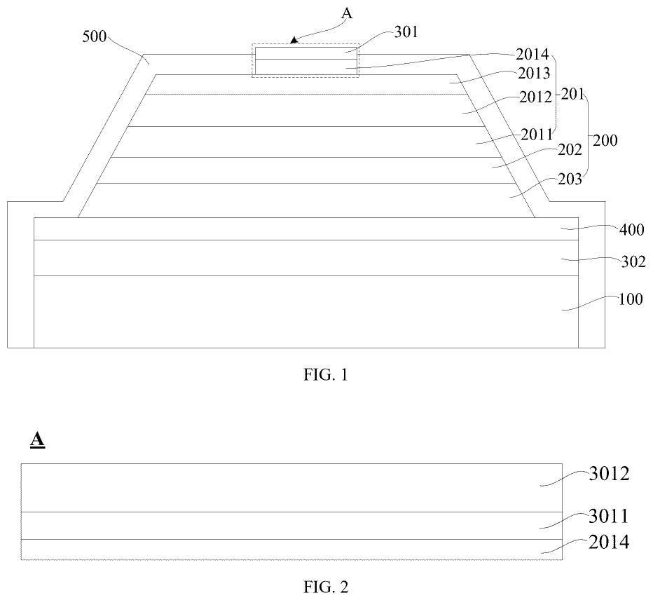

The embodiment provides a light-emitting diode. As shown in FIG. 1, the light-emitting diode of this embodiment includes a semiconductor stack 200 and an electrode structure. The semiconductor stack 200 can be any material that emits light under voltage, such as GaN, AlGaN, AlInP, AlGaInP, AlGaP, etc.

As shown in FIG. 1, the aforementioned semiconductor stack 200 is located above a substrate 100 and includes a first semiconductor layer 201, an active layer 202, and a second semiconductor layer 203 sequentially stacked from top to bottom. The first semiconductor layer 201, the active layer 202, and the second semiconductor layer 203 may include semiconductor material layers of Group III-V elements, for example, semiconductor material layers such as Al, Ga, In, or P. The first semiconductor layer 201 may include n-type impurities (e.g., Si, Ge, or Sn), and the second semiconductor layer 203 may include p-type impurities (e.g., Mg, Sr, or Ba). It should be understood that dopants in the first semiconductor layer 201 and the second semiconductor layer 203 may also be the opposite of the above.

The active layer 202 is a region where electrons and holes recombine to provide optical radiation. Different materials can be selected based on the desired emission wavelength. The material of the active layer 202 is an AlGaInP series, emitting light such as red, yellow, or orange light. The active layer 202 may have a single heterostructure (SH), double heterostructure (DH), double-sided double heterostructure (DDH), or multi-quantum well structure (MQW). The active layer 202 includes well layers and barrier layers, where the barrier layers have a larger bandgap than the well layers. By adjusting the composition ratio of the semiconductor material in the active layer 202, light of different wavelengths can be emitted. In this embodiment, the active layer 202 emits light in the wavelength range of 550 nanometers (nm) to 750 nm, such as red, yellow, or orange light, and further, emits red light. The active layer 202 is a material layer providing electroluminescent radiation, such as AlGaInP or AlGaAs, specifically AlGaInP, which may be a single quantum well or multi-quantum well.

In this embodiment, the aforementioned active layer 202 is optionally a multi-quantum well layer including alternately grown AlGaInP quantum well layers and AlGaInP quantum barrier layers, with different Al content in the AlGaInP quantum well layers and the AlGaInP quantum barrier layers. The multi-quantum well layer may include 1 to 200 periods of alternately stacked AlGaInP quantum well layers and AlGaInP quantum barrier layers. As an example, the multi-quantum well layer includes 5 periods of alternately stacked AlGaInP quantum well layers and AlGaInP quantum barrier layers.

As shown in FIG. 1, in a direction gradually facing away from the active layer 202 (i.e., the bottom-up direction in FIG. 1), the first semiconductor layer 201 in the semiconductor stack 200 may include a first spacer layer 2011, a first confinement layer 2012 (also referred to as first cladding layer), a first window layer 2013, and a semiconductor contact layer 2014 sequentially stacked. The first spacer layer 2011, the first confinement layer 2012, and the first window layer 2013 also use AlGaInP materials. For example, the first spacer layer 2011 uses AlGaInP material, the first confinement layer 2012 uses AlInP material, the first window layer 2013 uses AlGaInP material, and the semiconductor contact layer 2014 uses GaAs or AlGaInP material. The semiconductor contact layer 2014 formed from GaAs material is advantageous for forming a good ohmic contact with subsequently formed metal electrodes.

As shown in FIG. 1, the light-emitting diode of this embodiment includes the electrode structure, in which a first electrode 301 is formed above the first semiconductor layer 201 and is electrically connected to the first semiconductor layer 201. Specifically, the first electrode 301 contacts the semiconductor contact layer 2014 to form an ohmic contact. As shown in FIG. 2, the first electrode 301 in this embodiment includes a metal contact layer 3011 and a metal electrode layer 3012. The metal contact layer 3011 is arranged adjacent to the semiconductor contact layer 2014, and the metal electrode layer 3012 is arranged adjacent to the metal contact layer 3011. The metal contact layer 3011 contains Ni, and its thickness ranges from 5 Å to 100 Å. Furthermore, the Ni in the metal contact layer 3011 has good adhesion to the semiconductor contact layer 2014 and can form a good ohmic contact with the semiconductor contact layer 2014, reducing the resistance of the first electrode 301. In an embodiment, the aforementioned metal electrode layer 3012 is a multilayer structure including an Au layer. Further, the Au layer is arranged adjacent to the metal contact layer 3011 (Ni layer). For example, in an embodiment, the metal electrode layer 3012 is an Au/Ge/Ni stacked structure or an Au/AuGeNi/Au stacked structure. In an embodiment, a metal protective layer, such as Cu or Au, may also be formed on the surface of the metal electrode layer 3012.

In the related art, the metal electrode layer is formed as an alloy structure. During the formation of the metal electrode layer, a thermal process is involved. In this process, the semiconductor contact layer and the metal electrode layer form an ohmic contact. However, Au exhibits a self-agglomeration effect upon heating, especially when in direct contact with the semiconductor contact layer, where this effect is particularly pronounced. This can lead to non-uniform resistance in the electrode structure and consequently non-uniform brightness. This phenomenon is especially noticeable in small-sized light-emitting diodes. In contrast, as described above, in this embodiment, the metal contact layer 3011, during the thermal fusion process, has good diffusivity, enabling it to form a good ohmic contact with the semiconductor contact layer 2014. In addition, it can also effectively prevent the self-agglomeration effect of Au from the metal electrode layer 3012 during the diffusion process, allowing it to diffuse uniformly. This results in uniform diffusion and fusion for the first electrode 301, leading to correspondingly more uniform resistance and avoiding the agglomeration of low-resistance points.

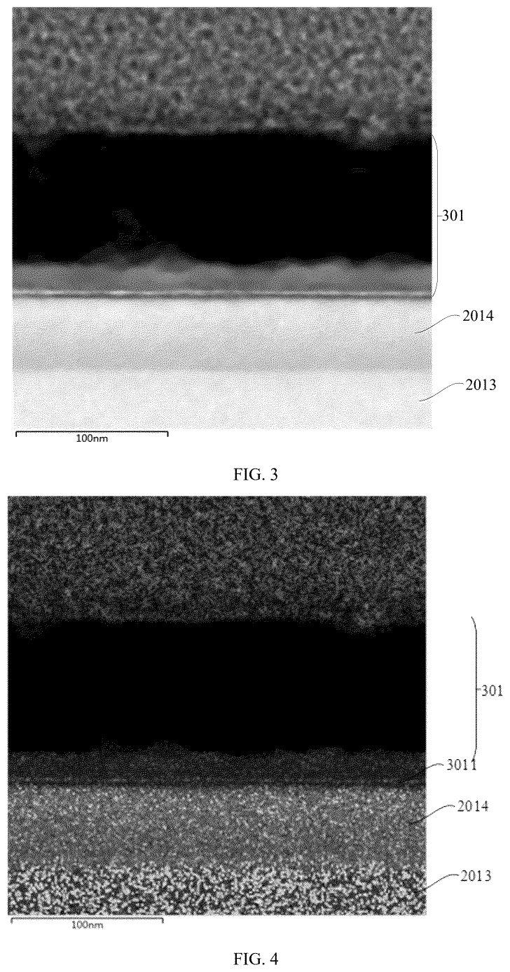

As shown in FIG. 3 and FIG. 4, the SEM image and the EDS image from a side of the first electrode 301 show that the elements in the metal contact layer 3011 and the semiconductor contact layer 2014 have interdiffused uniformly into each other's layers. A distinct Ni diffusion layer (i.e., metal contact layer 3011) exists between the semiconductor contact layer 2014 and the metal electrode layer 3012. Further experiments have proven that the content of Ni in the metal contact layer 3011 is greater than that in the metal electrode layer 3012, the content of Au in the metal contact layer 3011 is less than that in the metal electrode layer 3012, and the content of Ge in the metal contact layer 3011 is greater than that in the metal electrode layer 3012. In an embodiment, the content of Ni in the metal contact layer 3011 is greater than or equal to 10 wt%, further, greater than or equal to 30 wt%, 40 wt%, or even greater than or equal to 50 wt%; the content of Ge is greater than or equal to 30 wt%, further, greater than or equal to 40 wt%. In an embodiment, the content of Au in the metal contact layer 3011 is relatively low, for example, less than or equal to 20 wt%, further, less than or equal to 10 wt%. The distribution of elemental content in the first electrode indicates good diffusivity between the metal contact layer 3011 and the metal electrode layer 3012, and also shows that the metal contact layer 3011 can effectively prevent the self-agglomeration effect during the diffusion of Au from the metal electrode layer 3012 into the semiconductor contact layer 2014, improving the uniformity of the electrode structure.

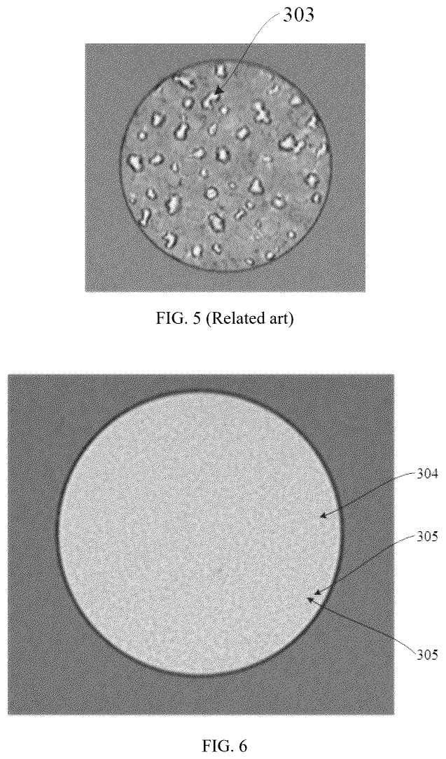

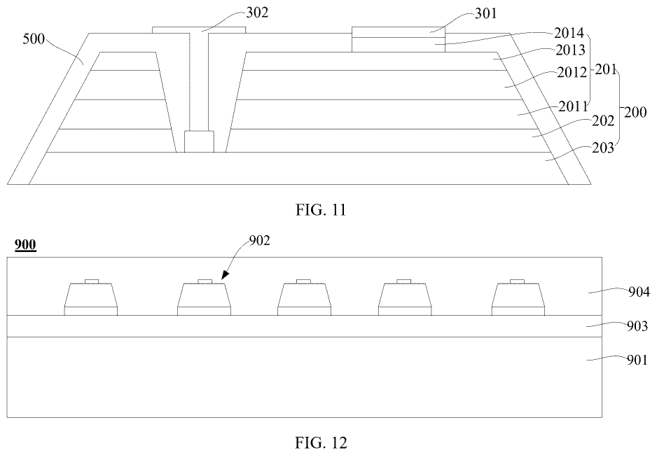

Combining FIG. 5, FIG. 6, FIG. 9, and FIG. 10, FIG. 5 shows a magnified microscopic image of an interface between a first electrode and a semiconductor contact layer according to a light-emitting diode in the related art (i.e., without the metal contact layer 3011 described in this embodiment). FIG. 6 shows a magnified microscopic image of an interface between the first electrode 301 and the semiconductor contact layer 2014 in the light-emitting diode of this embodiment. As seen in FIG. 5, in the related art, a large amount of Au agglomeration occurs at the interface between the metal electrode and the semiconductor contact layer. These Au agglomeration points (i.e., agglomerated particles) form areas of lower electrode resistance, while other parts have relatively higher resistance, resulting in non-uniform resistance distribution across the entire electrode. When voltage is applied to the first electrode 301, the voltage distribution is non-uniform, leading to non-uniform light emission from the light-emitting diode. As shown in FIG. 9, a display screen formed by the light-emitting diode in the related art exhibits non-uniform brightness or obvious bright spots. In contrast, as shown in FIG. 6, in the light-emitting diode of this embodiment, the metal contact layer 3011 of the first electrode 301 is in direct contact with the semiconductor contact layer 2014, and no metal agglomeration points exist at their interface. As shown in FIG. 6, diffusion traces 304 exist at the interface, forming diffusion points 305. The size of these diffusion points 305 (e.g., length, diameter, or the distance between the two farthest points of the diffusion points) is less than or equal to 1 μm, and the spacing distance between two adjacent diffusion points 305 is less than or equal to 1 μm. That is, all metals diffuse uniformly to form a uniform alloy, resulting in a uniformly distributed resistance for the first electrode 301. Consequently, when the voltage is applied to the first electrode 301, the voltage distribution is uniform, leading to uniform light emission from the light-emitting diode. As shown in FIG. 10, a display screen formed by the light-emitting diode of this embodiment has uniform brightness without phenomena such as bright spots. It can be seen that the metal contact layer 3011 of the first electrode 301 can effectively prevent the self-agglomeration phenomenon of Au from the metal electrode layer 3012 during diffusion, enabling uniform diffusion. Ultimately, the metal electrode forms a uniformly diffused alloy, improving its conductive uniformity.

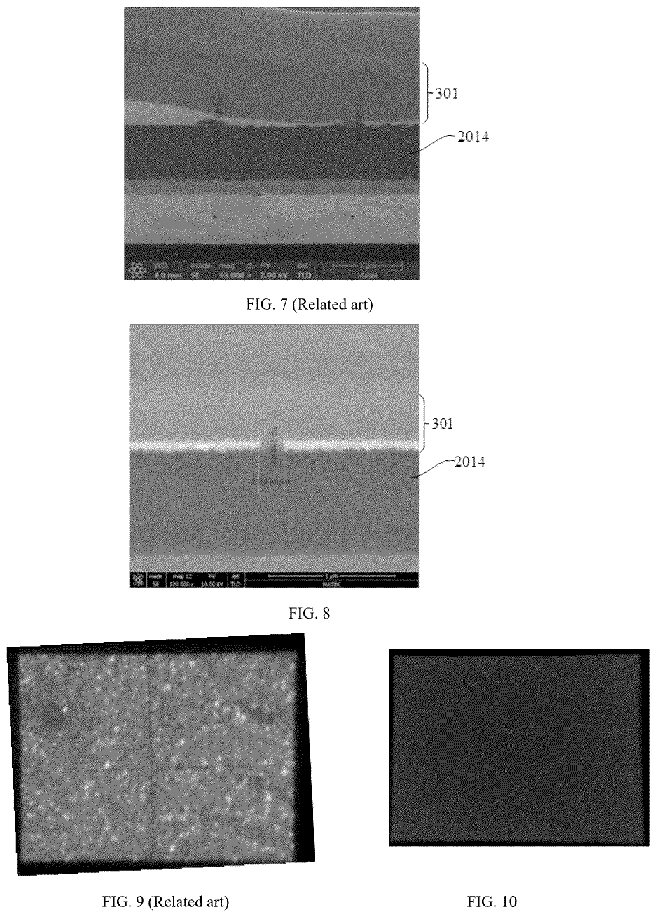

As shown in FIG. 7 and FIG. 8, FIG. 7 shows a FIB test image of a longitudinal section at the side of the first electrode of the light-emitting diode in the related art, indicating obvious agglomerated particles 303, forming granular protrusions of uneven sizes. That is, uneven agglomerated particles 303 exist at the interface between the first electrode 301 and the semiconductor contact layer 2014, indicating poor Au diffusion. As shown in FIG. 8, the interface between the metal contact layer 3011 and the semiconductor contact layer 2014 in the light-emitting diode of the disclosure shows no obvious particle agglomeration, the surface roughness is relatively uniform, with a roughness below 200 nm, for example, less than 150 nm, further, less than 125 nm. This interface characteristic is significantly better than that of the corresponding interface in the related art. This confirms that the first electrode 301 of this embodiment can form a good ohmic contact with the semiconductor contact layer 2014 while having good adhesion.

To ensure good interface characteristics between the first electrode 301 and the semiconductor contact layer 2014, their thicknesses are also important parameters. In an embodiment, the thickness of the aforementioned semiconductor contact layer 2014 ranges from 0.02 μm to 0.5 μm, for example, 0.05 μm, 0.1 μm, 0.3 μm, 0.4 μm, 0.5 μm. The thickness setting of the semiconductor contact layer 2014 is conducive to reducing its light absorption and improves the light extraction efficiency of the light-emitting diode. The thickness of the metal contact layer 3011 ranges from 5 Å to 100 Å, for example, 20 Å, 50 Å, 70 Å, 100 Å. On one hand, the thickness of the metal contact layer is controlled to ensure that a good ohmic contact layer is formed with the semiconductor contact layer 2014, and on the other hand, the metal contact layer 3011 is well fused with each metal layer of the metal electrode layer, so that the stability and the reliability of the electrode structure are ensured, and the obvious light absorption phenomenon cannot be generated. The thickness of the metal electrode layer 3012 ranges from 0.02 μm to 1 μm, for example, 0.05 μm, 0.1 μm, 0.3 μm, 0.5 μm, 0.7 μm, 1 μm. The total thickness of the first electrode 301 ranges from 0.02 μm to 1 μm, for example, 0.05 μm, 0.15 μm, 0.35 μm, 0.55 μm, 0.75 μm, 1 μm. The thickness of the first electrode 301 ensures the formation of a good ohmic contact with the semiconductor contact layer 2014, guaranteeing its good electrical performance.

As shown in FIG. 1, the second semiconductor layer 203 is located below the active layer 202. In an embodiment, the second semiconductor layer 203 at least includes a transition layer, a second spacer layer, and a second confinement layer (not specifically illustrated) sequentially stacked. The transition layer is adjacent to the active layer 202. The transition layer is formed from a material including AlGaInP. The second spacer layer uses AlGaInP material, and the second confinement layer uses AlInP material.

To further improve the light extraction efficiency of the light-emitting diode, in an embodiment, the surface of the N-type semiconductor layer serving as the light-emitting surface can also be formed as a rough surface. As shown in FIG. 1, the first electrode 301 is formed above the first semiconductor layer 201, i.e., on the light-emitting surface. To ensure good contact between the first electrode 301 and the first semiconductor layer 201, as well as the stability and electrical performance of the first electrode 301, while minimizing the impact of the side of the first electrode 301 on light emission, the first electrode 301 typically covers most of the surface area of the first semiconductor layer 201. In this embodiment, in a projection onto the plane of the light-emitting surface, the projected area of the first electrode 301 is less than or equal to the projected area of the semiconductor contact layer 2014. Specifically, the projected area of the first electrode 301 is equal to the projected area of the semiconductor contact layer 2014, thereby minimizing the surface area of the semiconductor contact layer 2014 and reducing its light absorption. The projected area of the first electrode 301 accounts for 50% to 100%, further, 50% to 90%, of the surface area of the light-emitting surface. For example, when the size of the light-emitting diode (i.e., the side length) is less than or equal to 5 μm, the single-side size of the first electrode 301 is above 2 μm, thereby ensuring good contact between the first electrode 301 and the first semiconductor layer 201 (specifically, the semiconductor contact layer 2014), and ensuring its stability and good electrical performance.

The light-emitting diode of this embodiment is formed as a vertical structure. The second electrode 302 of the electrode structure is formed between the substrate 100 and the second semiconductor layer 203. Specifically, as shown in FIG. 1, the light-emitting diode of this embodiment includes a transparent conductive layer 400 and the second electrode 302 between the substrate 100 and the semiconductor stack 200. The transparent conductive layer 400 can be, for example, a transparent conductive oxide such as indium tin oxide (ITO) or indium zinc oxide (IZO). In this embodiment, the aforementioned second electrode 302 is a metal layer, including but not limited to Au, Pt, GeAuNi, Ti, BeAu, GeAu, Al, or ZnAu, etc. In an embodiment, the second electrode 302 can also serve as a metal mirror, reflecting light radiated from the semiconductor stack 200 to be emitted from the side of the first semiconductor layer 201. In addition, the second electrode 302 also serves as a bonding layer with the substrate 100, bonding the semiconductor stack 200 to the substrate 100. The substrate 100 can be a drive panel, including drive circuits formed in the substrate 100 and multiple contact points connected to the drive circuits. The light-emitting diode is electrically connected to the multiple contact points. It should be understood that the substrate 100 may also be provided with a circuit layer including devices such as complementary metal-oxide-semiconductor (CMOS) devices or thin-film transistor (TFT) devices, which can constitute the drive circuit. The material of the substrate may be a semiconductor material such as Si, SiC, GaN, Ge, GaAs, or InP, or it may be a non-conductive material such as glass, plastic, or a sapphire wafer.

As shown in FIG. 1, the light-emitting diode of this embodiment further includes an protective insulation layer 500. This protective insulation layer 500 covers the light-emitting surface side, i.e., the surface of the first semiconductor layer 201, as well as the exposed sidewalls and other surfaces of the semiconductor stack 200 and the substrate 100. The protective insulation layer 500 may be formed from at least one material among SiO_{X}, SiN_{X}, SiO_{X}N_{Y}, Al₂O₃, and TiO_{X}. The protective insulation layer 500 can effectively protect the light-emitting diode, especially the semiconductor stack 200, from external moisture, impurities, etc., ensuring the performance of the light-emitting diode.

### Embodiment 2

This embodiment also provides a light-emitting diode. As shown in FIG. 11, the light-emitting diode of this embodiment also includes a semiconductor stack 200. The light-emitting diode is formed as a flip-chip structure light-emitting diode, in which both a first electrode 301 and a second electrode 302 of the electrode structure are formed on a side of the first semiconductor layer 201. In other embodiments, both the first electrode 301 and the second electrode 302 may also be formed on the side of the second semiconductor layer 203.

As shown in FIG. 11, in this embodiment, a protective insulation layer 500 covers the exposed surfaces of the semiconductor stack 200. The first electrode 301 is formed above the protective insulation layer 500, contacting the semiconductor contact layer 2014 and thereby being electrically connected to the first semiconductor layer 201. The second electrode 302 is also formed above the protective insulation layer 500. An electrode mesa 204 is formed in the semiconductor stack 200. This electrode mesa 204 is formed above the second semiconductor layer 203, and the second electrode 302 is formed on this electrode mesa 204 to be electrically connected to the second semiconductor layer 203. As shown in FIG. 11, the protective insulation layer 500 covers the exposed surfaces and sidewalls of the electrode mesa 204 to insulate the second electrode 302 from other layer structures of the semiconductor stack 200.

### Embodiment 3

This embodiment provides a semiconductor display device. As shown in FIG. 12, the display device 900 includes a circuit substrate 901 and multiple light-emitting units 902 electrically connected to the circuit substrate 901. In this embodiment, the light-emitting unit 902 is the light-emitting diode according to the embodiment 1 and/or the embodiment 2. As shown in FIG. 12, a wiring layer 903 is disposed in the circuit substrate 901, and the light-emitting units 902 are electrically connected to the wiring layer 903. As shown in FIG. 12, the display device 900 may further include a housing 904 to protect the light-emitting units 902 from external contamination or damage while not affecting the light extraction efficiency of the light-emitting units. The arrangement of the wiring layer and bonding pad areas of the light-emitting diode of the disclosure increases its bonding force when fixed to the aforementioned pads, improving the reliability of the device.

The above embodiments are merely illustrative of the principles and efficacy of the disclosure and are not intended to limit the disclosure. Any person skilled in the art may modify or change the above embodiments without departing from the spirit and scope of the disclosure. Therefore, all equivalent modifications or changes made by those skilled in the art without departing from the spirit and technical concepts disclosed in the disclosure shall still be covered by the claims of the disclosure.

What is claimed is:

1. A light-emitting diode, comprising:
a semiconductor stack, comprising a first semiconductor layer, an active layer, and a second semiconductor layer sequentially stacked from top to bottom; and
an electrode structure, comprising a first electrode electrically connected to the first semiconductor layer and a second electrode electrically connected to the second semiconductor layer; and
wherein a semiconductor contact layer is formed between the first semiconductor layer and the first electrode; the first electrode comprises a metal contact layer and a metal electrode layer sequentially stacked above the semiconductor contact layer; the metal contact layer comprises nickel (Ni), and the metal electrode layer is a multilayer structure or an alloy structure comprising at least gold (Au).

2. The light-emitting diode as claimed in claim 1, wherein diffusion points are formed at an interface between the metal contact layer and the semiconductor contact layer, a size of each diffusion point is less than or equal to 1 micrometer (μm), and a spacing distance between two adjacent diffusion points is less than or equal to 1 μm.

3. The light-emitting diode as claimed in claim 1, wherein the metal electrode layer is the alloy structure comprising the Au, germanium (Ge), Ni.

4. The light-emitting diode as claimed in claim 3, wherein a content of the Ni in the metal contact layer is greater than a content of the Ni in the metal electrode layer, a content of Au in the metal contact layer is less than a content of the Au in the metal electrode layer, and a content of Ge in the metal contact layer is greater than a content of the Ge in the metal electrode layer.

5. The light-emitting diode as claimed in claim 3, wherein the content of Ni in the metal contact layer is greater than or equal to 10 weight percent (wt%).

6. The light-emitting diode as claimed in claim 3, wherein a thickness of the metal contact layer is in a range of 5 angstroms (Å) to 100 Å.

7. The light-emitting diode as claimed in claim 5, wherein a thickness of the metal electrode layer is in a range of 0.02 μm to 1 μm.

8. The light-emitting diode as claimed in claim 1, wherein a material of the semiconductor contact layer is gallium arsenide (GaAs) or aluminum gallium indium phosphide (AlGaInP).

9. The light-emitting diode as claimed in claim 1, wherein the semiconductor stack is an AlGaInP-based semiconductor material layer.

10. The light-emitting diode as claimed in claim 1, wherein the first electrode is formed on a side of the first semiconductor layer facing away from the active layer, and the second electrode is formed on a side of the second semiconductor layer facing away from the active layer.

11. The light-emitting diode as claimed in claim 1, wherein the first electrode and the second electrode both are formed on a side of the first semiconductor layer facing away from the active layer.

12. The light-emitting diode as claimed in claim 1, wherein in a projection onto a plane of the semiconductor stack, a projected area of the first electrode is less than or equal to a projected area of the semiconductor contact layer.

13. The light-emitting diode as claimed in claim 1, wherein in a projection onto a plane of the semiconductor stack, a surface area of the first electrode accounts for 50% to 100% of a surface area of the first semiconductor layer.

14. The light-emitting diode as claimed in claim 1, wherein a maximum single-side length of the light-emitting diode is less than or equal to 5 μm.

15. A display device, comprising a substrate and a plurality of light-emitting units located on the substrate, wherein each light-emitting unit comprises the light-emitting diode as claimed in claim 1.
